(19) United States
(12) Patent Application Publication
(10) Pub. No.: US 2026/0295859 A1
(43) Pub. Date: Oct. 1, 2026

(54) A POSITIONING SYSTEM FOR POSITIONING AN OBJECT WITHIN AN XYZ-SYSTEM OF COORDINATES

(71) Applicant: VDL ENABLING TECHNOLOGIES GROUP B.V., EINDHOVEN (NL)

(72) Inventors: Johannes Hubertus Antonius VAN DE RIJDT, EINDHOVEN (NL); Rob Antonius Andries VERKOOIJEN, EINDHOVEN (NL); Johannes Wilhelmus DE KLERK, EINDHOVEN (NL)

(21) Appl. No.: 18/998,089

(22) PCT Filed: Jul. 19, 2023
(86) PCT No.: PCT/NL2023/050387

§ 371 Date: Jan. 23, 2025

(30) Foreign Application Priority Data
Jul. 27, 2022 (NL) 2032608

(51) Int. Cl. B25J 11/00; B25J 9/12; G03F 7/00; H10P 72/50

(52) U.S. Cl. CPC B25J 11/0095; B25J 9/12; G03F 7/70716; G03F 7/70758; H10P 72/50

(57) ABSTRACT

According to the disclosure, a positioning system for positioning an object within an XYZ-system of coordinates is proposed, with the positioning system comprising a supporting structure, an object table for supporting the object and a positioning module structured for positioning the object table relative to the supporting structure within the XYZ-system of coordinates, wherein the positioning module comprises a frame for supporting the object table and at least three actuator devices, each structured for positioning the frame in the Z-direction of the XYZ-system of coordinates.

### TECHNICAL FIELD

The present disclosure relates to the technique of positioning an object within an XYZ-system of coordinates. In particular, the disclosure pertains to so-called wafer substrate positioning systems of the Z-axis stage type. Z-axis stage type positioning systems are also known as vertical stages, which provide a controlled positioning of an object along the z-axis of an XYZ-system of coordinates. Such Z-axis stage type positioning systems are e.g. used in product processing applications under high or low vacuum (or clean room) conditions.

### BACKGROUND OF THE DISCLOSURE

In product processing applications under high or low vacuum (or clean room) conditions or even under atmospherics conditions, for example but not limited to wafer handling applications in the semiconductor manufacturing industry, an increasing demand for improved process reliability and stability as well as more accurate position handling combined with a higher throughput of products exists.

These requirements in vacuum operated product process environment set high standards with respect to the positioning and the orientation of a product, such as a wafer, during the many, subsequent process steps. In particular, vibrations created in the process line by moving mechanical parts and/or by the electrical component circuit may adversely affect the positioning accuracy of the product to be processed within the process line.

Reduction of vibrations can be realized by implementing air bearings or roller bearings, possibly in combination with piezo-actuators. In the presently known Z-axis stage type positioning systems, the main challenges of applying air bearings in high-tech in-vacuum systems or under atmospheric conditions is their limit in positioning performance, in particular they are vulnerable to position errors, i.e. ‘jitter’.

Accordingly, it is a goal of the present disclosure to provide a Z-axis stage type positioning system with a more sophisticated setting ability in the Z-direction and with limited position errors.

### SUMMARY OF THE DISCLOSURE

According to a first example of the disclosure, a positioning system for positioning an object within an XYZ-system of coordinates is proposed, with the positioning system comprising a supporting structure, an object table for supporting the object and a positioning module structured for positioning the object table relative to the supporting structure within the XYZ-system of coordinates, wherein the positioning module comprises a frame for supporting the object table and at least three actuator devices, each structured for positioning the frame in the Z-direction of the XYZ-system of coordinates.

The three actuator devices provide accurate displacements and/or positioning of the object table in the Z-direction through their associate Rx, Ry and z movements (degrees of freedom, DOF). Furthermore, this construction has a simple configuration, which can be actuated in a less complex manner compared to known Z-stage applications.

In addition, in a further example the positioning module may comprise at least one further actuator device structured to rotate the frame around the Z-axis of the XYZ-system of coordinates. Herewith an efficient setting mechanism is achieved, allowing accurate positioning of the object table in the XYZ-system of coordinates in particular in the z-direction thereof

In a preferred example, the frame is formed as a triangle shaped frame, and wherein each of said at least three actuator devices are mounted at a vertex of the triangle shaped frame. Furthermore, in this particular example, the at least one further actuator device may be mounted to an edge of the triangle shaped frame. Accordingly, this example has the characteristics of low weight, versatile and accurate positioning of the object table at relatively fast setting times.

In a particular example, each actuator device is constructed as a Lorentz-type actuator and alternatively as a variable reluctance magnetic bearing assembly. Such actuators and their accompanying sensors (encoders) are more or less standard building blocks, which result, with respect to a known full 6-DoF Maglev solution (an alternative position technique), in a relative low amount of required non recurrent engineering (NRE) effort and low cost-of-goods.

The use of such actuators and their mounting in the Z-stage positioning system according to the disclosure provides adequate isolation of vibrations from the ‘outside’ world, for example from floor vibrations, contrary to presently used solutions, such as roller bearings which provide much less vibration isolation. The isolation results in a better positioning performance without the need, or less need, for all kinds of active vibration isolation systems or vibration compensation methods.

Alternatively, the positioning module may comprise an XY setting mechanism for orienting the frame in the XY-plane of the XYZ-system of coordinates. This creates a more sophisticated positioning system with two additional degrees of freedom, DOF, in the x-direction and y-direction of the XYZ-system of coordinates.

More alternatively, in another example the XY setting mechanism does not serve to provide additional positioning in the x-direction and y-direction of the XYZ-system of coordinates, contrary to that, the XY setting mechanism is structured to restrain or constrain the frame and thus the object table in the XY-plane of the XYZ-system of coordinates. Herewith, the Z-axis stage type positioning system is kept stable in both the x-direction and y-direction (in other words in the XY plane parallel to the horizontal). This example of the XY setting mechanism provides stiffness/stability in the x-direction and y-direction.

### BRIEF DESCRIPTION OF THE DRAWINGS

The disclosure will now be discussed with reference to the drawings, which show in:

FIGS. 1-3 a frontal, side and top view of an example of a Z-axis stage positioning system according to the disclosure.

### DETAILED DESCRIPTION OF THE DISCLOSURE

For a proper understanding of the disclosure, in the detailed description below corresponding elements or parts of the disclosure will be denoted with identical reference numerals in the drawings.

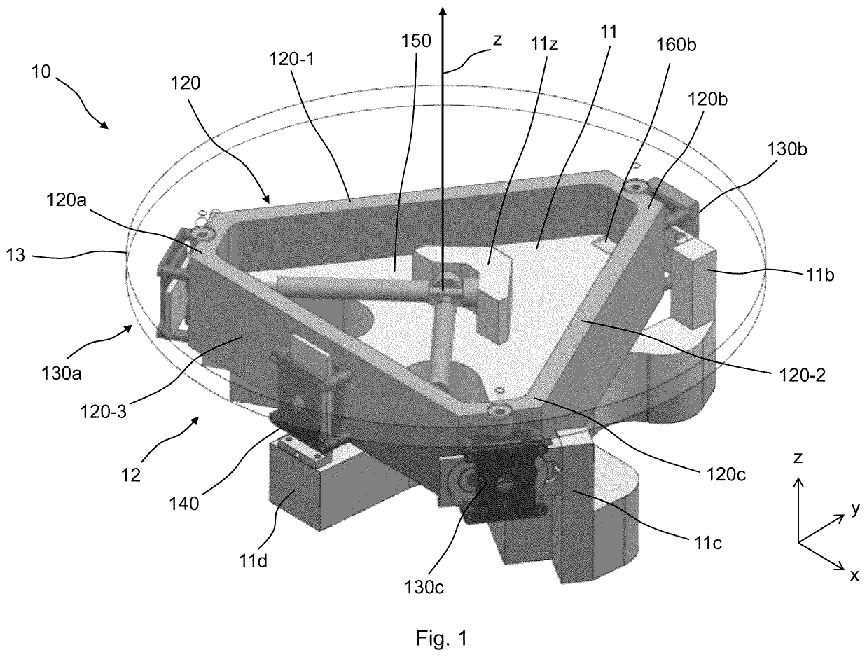

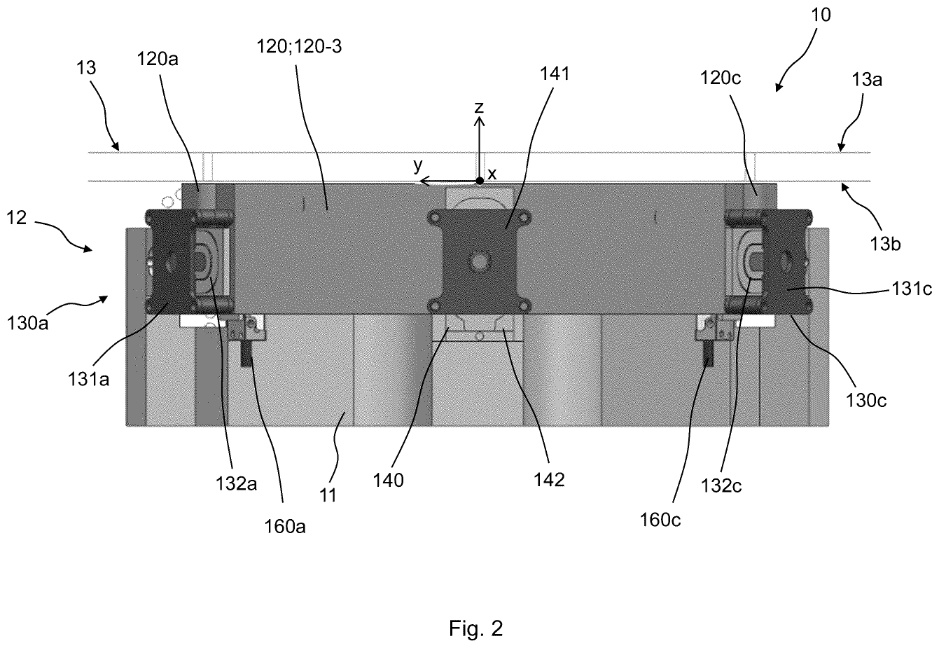

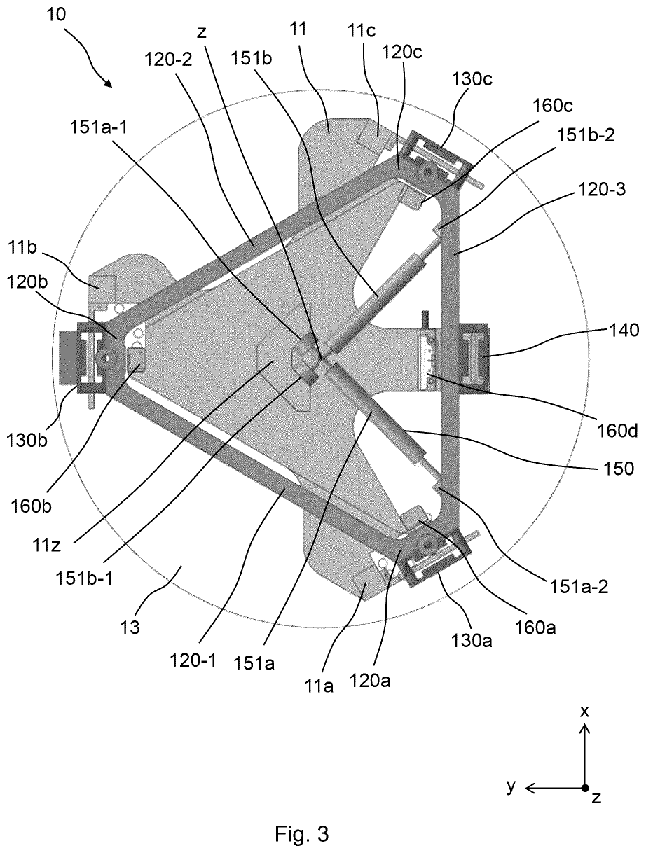

FIGS. 1-3 depict a frontal, a side view and a top view of an example of a positioning system according to the disclosure. In particular, the disclosure pertains to so-called wafer substrate positioning systems of the Z-axis stage type. Z-axis stage type positioning systems are also known as vertical stages, which provide a controlled positioning of an object along the z-axis of an XYZ-system of coordinates. Such Z-axis stage type positioning systems are e.g. used in product processing applications under high or low vacuum (or clean room) or even under atmospheric conditions.

As outlined in the introduction part of this description, in the presently known Z-axis stage type positioning systems, the main challenges of applying air bearings or roller bearings in high-tech in-vacuum systems but also under atmospheric conditions is their limit in positioning performance, in particular they are vulnerable to position errors, i.e. ‘jitter’.

The present disclosure aims to provide a Z-axis stage type positioning system with a more sophisticated setting ability in the Z-direction and with limited position errors.

An example of such Z-axis stage type positioning system according to the disclosure is depicted in the various views of FIGS. 1-3. The example of the positioning system for positioning an object within an XYZ-system of coordinates is denoted with reference numeral 10 and comprises a supporting structure 11, which may function as the stable, solid world. Reference numeral 12 denotes a positioning module or metrology unit mounted to the supporting structure 11, and supports an object table or chuck 13.

The object table or chuck 13 serves to support a substrate wafer or similar product or object(not shown), which is to be subjected for example to photolithography process steps in a process chamber (also not shown), which process steps require extreme high accuracy as to motion and positioning under vacuum conditions. The object table 13 can be provided with a recess (not shown) for accommodating a substrate wafer (the object).

As shown in the Figures, the positioning module or metrology unit 12 is mounted in the supporting structure 11 with the object table or chuck 13 mounted on the positioning module 12. The supporting structure 11 can additionally be provided with additional mass or auxiliary means, for example for cooling, supporting stability and providing accuracy to the positioning module 12 and the chuck 13 during operation.

The object table 13 can be positioned by means of the positioning module 12 relative to the supporting structure 11 within the XYZ-system of coordinates, depicted by the orthogonal axes x-y-z in the Figures. In particular, the Z-axis stage type positioning system according to the disclosure is intended to accurately position the object table 13 in the z-direction of the XYZ-system of coordinates.

As shown in the Figures, the positioning module 12 comprises a frame 120 for supporting the object table 13 and at least three first actuator devices 130a-130b-130c. Each actuator device 130a-130b-130c is structured for positioning the frame 120 in the z-, Rx- and Ry-direction of the XYZ-system of coordinates and relative to the supporting structure 11.

In the shown example, the frame 120 is formed as a triangle shaped frame and composed of three edges 120-1, 120-2 and 120-3 interconnected to each other at the vertices 120a-120b-120c. Each of said at least three actuator devices 130a-130b-130c are mounted at a vertex 120a-120b-120c of the triangle shaped frame 120. The three actuator devices 130a-130b-130c provide accurate displacements and/or positioning of the object table 13 in the z-direction through their associate Rx, Ry and z movements (degrees of freedom, DOF). Furthermore, this construction has a simple configuration, which can be actuated in a less complex manner compared to known z-stage applications.

Furthermore, in this example shown, the positioning module 12 may comprise at least one further actuator device, denoted with reference numeral 140. This further actuator device 140 has the functionality to rotate the frame 120 around the z-axis z of the XYZ-system of coordinates, also noted as the Rz-direction. This results in a setting mechanism, allowing an efficient yet accurate positioning of the object table 13 in the XYZ-system of coordinates in particular in the Rz-direction thereof.

The at least one further actuator device 140 may be mounted to one of the edges 120-1, 120-2, 120-3 of the triangle shaped frame 120, here at the edge 120-3 between the first actuator devices 130a and 130c, and in particular mounted at the center of the edge 120-3. Such construction has a low weight, exhibiting versatile and accurate positioning of the object table 13 relative to the supporting structure and at relatively fast setting times.

The concept as shown in FIGS. 1-3 is a relatively simple construction of a Z-axis stage type positioning system 10 according to the disclosure. The triangular shaped frame 120 of the positioning module 12 can be effectively positioned with the aid of four Lorentz or reluctance actuators. Three of the actuators (reference numerals 130a-130b-130c) actuate the triangle frame 120 in the vertical (z) direction and thus provide tilting Rx, Ry and z movements within the XYZ-system of coordinates. The fourth, further actuator device 140 is placed on one to the side edges 120-1, 120-2 or 120-3 of the triangle frame 120 and rotates the frame 120 around the z-axis (Rz-direction).

An object table or chuck 13 can be placed with its second, bottom object table surface 13b on the triangle frame 120. On the first, top object table surface 13a (opposite to the second, bottom surface 13b) a substrate or wafer (not shown) can be positioned. With this construction the object table 13 (and the wafer) can be positioned in four degrees of freedom (4-DOF).

In a particular example, each first actuator device 130a-130b-130c and further actuator device 140 is constructed as a Lorentz-type actuator and alternatively as a variable reluctance magnetic bearing assembly. Such actuators and their accompanying sensors (encoders) 160a-160b-160c-160d are more or less standard building blocks, which result, with respect to a known full 6-DoF Maglev solution (an alternative position technique), in a relative low amount of required non recurrent engineering (NRE) effort and low cost-of-goods.

The use of such actuators and their mounting in the Z-stage positioning system according to the disclosure provides adequate isolation of vibrations from the ‘outside’ world, for example from floor vibrations, contrary to presently used solutions, such as roller bearings which provide much less vibration isolation. The isolation results in a better positioning performance without the need, or less need, for all kinds of active vibration isolation systems or vibration compensation methods.

Accordingly, each first actuator device 130a-130b-130c and further actuator device 140 may comprise magnet coils 132a-132b-132c and 142, which are mounted to the solid world formed by the supporting structure 11. For mounting purposes the supporting structure 11 may comprise suitable mounting points or mounting cams 11a-11b-11c for accommodating the mounting of the magnet coils 132a-132b-132c of the corresponding first actuator devices 130a-130b-130c. Permanent magnets 131a-131b-131c are mounted at the vertices 120-a-120b-120c of the triangle-shaped frame 120. The permanent magnets 131a-131b-131c are made from a ferromagnetic material for proper interaction with the magnet coils 132a-132b-132c mounted to the supporting structure 11. Similarly, the further actuator device 140 may comprise a static bearing 141 of ferromagnetic material mounted to one of the edges 120-1, 120-2, 120-3 of the triangle shaped frame 120. The static bearing 141 interacts with a corresponding magnetic coil 142 connected to a mounting point or mounting cam 11d of the supporting structure 11. The four Lorentz or reluctance actuators 130a-130b-130c and 140 allow for an effective positioning of the triangular shaped frame 120 of the positioning module 12 relative to the supporting structure 11. Accordingly, the Z-axis stage type positioning system 10 according to the disclosure allow an efficient and accurate positioning of the object table 13 with four degrees of freedom (4-DOF).

Alternatively, the positioning module 12 may comprise an XY setting mechanism 150 for orienting the frame 120 in the XY-plane of the XYZ-system of coordinates. This creates a more sophisticated positioning system with two additional degrees of freedom, DOF, in the x-direction and y-direction of the XYZ-system of coordinates. The XY setting mechanism 150 may comprise first and second setting spindles 151a-151b, of which the rods are flexible yet only stiff in a single degree of freedom (X or Y direction) and of which a length dimension can be altered in a known fashion. In an example, the flexible rod actuator may include a piezo-actuator allowing for inducing small movements in the X and/or Y direction.

Each first and second setting spindle 151a-151b comprises first spindles ends 151a-1 and 151b-1 which are mounted to a center cam 11z of the supporting structure 11. The connection point of both first spindles ends 151a-1 and 151b-1 lies in the z-as orientation of the XYZ-system of coordinates.

Each first and second setting spindle 151a-151b is mounted at some distance from each other with their second ends 151a-2, 151b-2 with an edge 120-3 of the triangle shaped frame 120. A length extension or length shortening of the first and second setting spindle 151a-151b relative to the center z-axis z causes a corresponding displacement of the triangle shaped frame 120 in the x-direction and/or y-direction of the XYZ-system of coordinates.

However, in another example it can be preferred that the Z-axis stage type positioning system 10 according to the disclosure and in particular the object table or chuck 13 should be maintained in a stable position in these other two degrees of freedom: the x and y-direction (the horizontal plane). Accordingly, in that particular example the XY setting mechanism 150 does not serve to provide additional positioning in the x-direction and y-direction of the XYZ-system of coordinates. Contrary to that, the XY setting mechanism 150 is structured to restrain or constrain the (triangle shaped) frame 120 and thus the object table or chuck 13 in the XY-plane of the XYZ-system of coordinates. Herewith, the Z-axis stage type positioning system 10 is kept stable in both the x-direction and y-direction (in other words in the XY plane parallel to the horizontal) and the XY setting mechanism 150 provides stiffness/stability in the x-direction and y-direction.

### LIST OF REFERENCE NUMERALS USED

10 positioning system according to the disclosure
11 supporting structure
11a-11c mounting cam of supporting structure
11z center cam of supporting structure
12 positioning module
13 object table or chuck
13a first, top surface of object table or chuck
13b second, bottom surface of object table or chuck
120 frame
120-1-120-3 edge of the triangle shaped frame
120a-120c vertex of the triangle shaped frame
130a-130c actuator device at each vertex of the triangle shaped frame
131a-131c permanent magnet of actuator device (Lorentz actuator)
132a-132c coil of actuator device (Lorentz actuator)
140 further actuator device at an edge of the triangle shaped frame
141 permanent magnet of further actuator device (Lorentz actuator)
142 coil of further actuator device (Lorentz actuator)
150 XY setting mechanism
151a first setting spindle/flexible rod
151b second setting spindle/flexible rod
151a-1/b-1 first end of first/second setting spindle/flexible rod
151a-2/b-2 second end of first/second setting spindle/flexible rod
160a-160d encoder
X x-axis
y y-axis
Z z-axis

1. A positioning system for positioning an object within an XYZ-system of coordinates, the positioning system comprising a supporting structure, an object table for supporting the object and a positioning module structured for positioning the object table relative to the supporting structure within the XYZ-system of coordinates, wherein the positioning module comprises a frame for supporting the object table and at least three actuator devices, each structured for positioning the frame in the Z-direction of the XYZ-system of coordinates.

2. The positioning system according to claim 1, wherein the positioning module comprises at least one further actuator device structured to rotate the frame around the Z-axis of the XYZ-system of coordinates.

3. The positioning system according to claim 1, wherein the frame is formed as a triangle shaped frame, and wherein each of said at least three actuator devices are mounted at a vertex of the triangle shaped frame.

4. The positioning system according to claim 3, wherein the at least one further actuator device is mounted to an edge of the triangle shaped frame.

5. The positioning system according to claim 1, wherein each actuator device is constructed as a Lorentz type actuator.

6. The positioning system according to claim 1, wherein each actuator device is constructed as a variable reluctance magnetic bearing assembly.

7. The positioning system according to claim 1, wherein the positioning module comprising an XY setting mechanism for orienting the frame in the XY-plane of the XYZ-system of coordinates.

8. The positioning system according to claim 7, wherein the XY setting mechanism is structured to restrain the frame in the XY-plane of the XYZ-system of coordinates.

9. The positioning system according to claim 7, wherein the XY setting mechanism comprises a spindle actuator.

10. The positioning system according to claim 7, wherein the XY setting mechanism comprises a flexible rod actuator.

11. The positioning system according to claim 10, wherein the flexible rod actuator includes a piezo-actuator.
